(19) United States
(12) Patent Application Publication
(10) Pub. No.: US 2018/0115306 A1
(43) Pub. Date: Apr. 26, 2018

(54) LOW POWER MASTER-SLAVE FLIP-FLOP

(71) Applicant: Advanced Micro Devices, Inc., Sunnyvale, CA (US)

(72) Inventors: Deepon Saha, Bangalore (IN); Arun Sundaresan Iyer, Bangalore (IN)

(21) Appl. No.: 15/298,871

(22) Filed: Oct. 20, 2016

(51) Int. Cl. H03K 3/012; H03K 3/3562

(52) U.S. Cl. CPC H03K 3/012; H03K 3/35625

(57) ABSTRACT

A native edge-triggered master-slave flip-flop exploits native latch topologies to create an edge-triggered master-slave flip-flop using a single clock phase having substantially reduced clock power consumption and substantially improved hold timing margin as compared to the clock power consumption and hold timing margin of a conventional master-slave flip-flop and other low power flip-flops.

### BACKGROUND

### Field of the Invention

The present invention is related to integrated circuits and more particularly to storage devices of integrated circuits.

### Description of the Related Art

In general, a decrease in power consumption of an integrated circuit included in portable applications or other target applications increases the battery life and may provide an advantage in the marketplace. Clock switching from global clock distribution, local clock distribution (e.g., Clock Tree Synthesis (CTS)), or synchronous devices (e.g., flip-flops) is a substantial source of integrated circuit power consumption. The latter components, e.g., CTS and flip-flop power consumption, are interrelated, since CTS is meant to distribute clock signals from the global distribution to all flip-flops in a physical area. However, data indicates that flip-flop power consumption dominates total integrated circuit power consumption in some applications. For example, flip-flops included in a processor core consume four times more power than CTS. In an exemplary Graphics Processing Unit (GPU), flip-flops consume three to three-and-a-half times more power than CTS. In some portions of the integrated circuit, the flip-flop power consumption is approximately the same as power consumption due to CTS. Accordingly, improved flip-flop topologies that consume less power are desired.

### SUMMARY OF EMBODIMENTS OF THE INVENTION

In at least one embodiment of the invention, an apparatus includes a clock node configured to receive a single-phase clock signal and an input node configured to receive an input signal. The apparatus includes a complementary input node configured to receive a complementary input signal that is complementary to the input signal. The apparatus further includes first differential latch. The first differential latch includes a first pair of complementary devices including a first device of a first type and a second device of a second type and includes a second pair of complementary devices cross-coupled to the first pair of complementary devices. The second pair of complementary devices includes a third device of the first type and a fourth device of the second type. The differential latch further includes a first pair of input devices including a fifth device of the first type and a sixth device of the first type and a second pair of input devices including a seventh device of the second type and an eighth device of the second type. The first pair of input devices and the second pair of input devices are configured to write an intermediate node with the complementary input signal and to write a complementary intermediate node with the input signal in response to a first state of the single-phase clock signal.

The apparatus may include a second differential latch connected to the clock node. The second differential latch may be complementary to the first differential latch and configured to update an output node and a complementary output node based on the first intermediate node and the complementary intermediate node and in response to a second state of the single-phase clock signal. The first and second differential latches may be configured as an edge-triggered master-slave flip-flop. The edge-triggered master-slave flip-flop may not include a transmission gate. The edge-triggered master-slave flip-flop may operate using the single-phase clock signal and no additional phases of the clock signal. The edge-triggered master-slave flip-flop may include at most six transistors driven by the clock signal. The edge-triggered master-slave flip-flop may include only four transistors connected to the clock node.

In at least one embodiment of the invention, a method includes providing a first reference voltage to a first storage element. The method includes providing a second reference voltage to one of a first node of the first storage element and a complementary first node of the first storage element according to an input signal and a complementary input signal during a first state of a clock signal. The method includes writing the first node with the complementary input signal and writing the complementary first node with the input signal using the first reference voltage and the second reference voltage during the first state of the clock signal. The method may include providing the second reference voltage to a second storage element. The method may include providing the first reference voltage to one of a second node of the second storage element and a complementary second node of the second storage element according to the intermediate signal and the complementary intermediate signal during a second state of the clock signal. The method may include writing the second node with an intermediate signal on the complementary first node and writing the complementary second node with a complementary intermediate signal on the first node using the first reference voltage and the second reference voltage during the second state of the clock signal. The method may include providing the second reference voltage to the first storage element during the second state of the clock signal and providing the first reference voltage to the second storage element during the first state of the clock signal. The first storage element and the second storage element may be included in an edge-triggered master-slave flip-flop using the clock signal and no additional phases of the clock signal.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a logic diagram of a conventional pass-gate based master-slave flip-flop.

FIG. 2 illustrates a logic diagram of a conventional multi-bit master-slave flip-flop.

FIG. 3 illustrates a logic diagram of a conventional pulsed flip-flop.

FIG. 4 illustrates a circuit diagram of an exemplary native active low latch consistent with at least one embodiment of the invention.

FIG. 5 illustrates a circuit diagram of an exemplary native active high latch consistent with at least one embodiment of the invention.

FIG. 6 illustrates a circuit diagram of an exemplary native rising-edge-triggered master-slave flip-flop consistent with at least one embodiment of the invention.

FIG. 7 illustrates a circuit diagram of an exemplary native falling-edge-triggered master-slave flip-flop consistent with at least one embodiment of the invention.

FIG. 8 illustrates a circuit diagram of an exemplary native falling-edge-triggered master-slave flip-flop configured as a rising-edge-triggered master-slave flop-flop by receiving a complementary clock signal with reduced input clock loading consistent with at least one embodiment of the invention.

FIG. 9 illustrates a circuit diagram of an exemplary native active low latch consistent with at least one embodiment of the invention.

FIG. 10 illustrates a circuit diagram of an exemplary native active high latch consistent with at least one embodiment of the invention.

FIG. 11 illustrates a circuit diagram of an exemplary native rising-edge-triggered master-slave flip-flop consistent with at least one embodiment of the invention.

FIG. 12 illustrates a circuit diagram of an exemplary native falling-edge-triggered master-slave flip-flop consistent with at least one embodiment of the invention.

FIG. 13 illustrates a circuit diagram of an exemplary native rising-edge-triggered master-slave flip-flop configured as a falling-edge-triggered master-slave flop-flop by receiving a complementary clock signal with reduced input clock loading consistent with at least one embodiment of the invention.

FIG. 14 illustrates a circuit diagram of an exemplary native active low latch consistent with at least one embodiment of the invention.

FIG. 15 illustrates a circuit diagram of an exemplary native active high latch consistent with at least one embodiment of the invention.

FIG. 16 illustrates a circuit diagram of an exemplary native rising-edge-triggered master-slave flip-flop consistent with at least one embodiment of the invention.

FIG. 17 illustrates a circuit diagram of an exemplary native falling-edge-triggered master-slave flip-flop consistent with at least one embodiment of the invention.

FIG. 18 illustrates a circuit diagram of an exemplary native rising-edge-triggered master-slave flip-flop configured as a falling-edge-triggered master-slave flop-flop by receiving a complementary clock signal with reduced input clock loading consistent with at least one embodiment of the invention.

The use of the same reference symbols in different drawings indicates similar or identical items.

### DETAILED DESCRIPTION

A native edge-triggered master-slave flip-flop exploits native latch topologies to create an edge-triggered master-slave flip-flop using a single clock phase having substantially reduced clock power consumption and substantially improved hold timing margin as compared to the clock power consumption and hold timing margin of a conventional master-slave flip-flop. The native edge-triggered master-slave flip-flop is formed from a native active low latch (i.e., a native B-latch) and a native active high latch (i.e., a native A-latch) and includes, at most, six clocked transistors, i.e., transistors having a gate terminal coupled directly to a clock net (or clock terminal) of the latch. Those native latches may each be driven directly by a clock net or through an inverted version of the single clock phase, which reduces external capacitive loading. The native A-latch and the native B-latch use complementary circuit topologies. The native A-latch and the native B-latch may be cascaded together to form a native rising-edge-triggered master-slave flip-flop or as a native falling-edge-triggered master-slave flip-flop. In at least one embodiment, each of the native latches includes two clocked transistors (one n-type transistor and one p-type transistor) and the native edge-triggered master-slave flip-flop includes only four clocked transistors driven directly by the clock net, with a total of twenty transistors. The reduced number of transistors in each native latch reduces wire loading of the clock net, area, and clock power consumption of each instantiation of a flip-flop as compared to a conventional edge-triggered master-slave flip-flop. The native edge-triggered master-slave flip-flop topology has reduced dynamic power consumption and low hold time requirements.

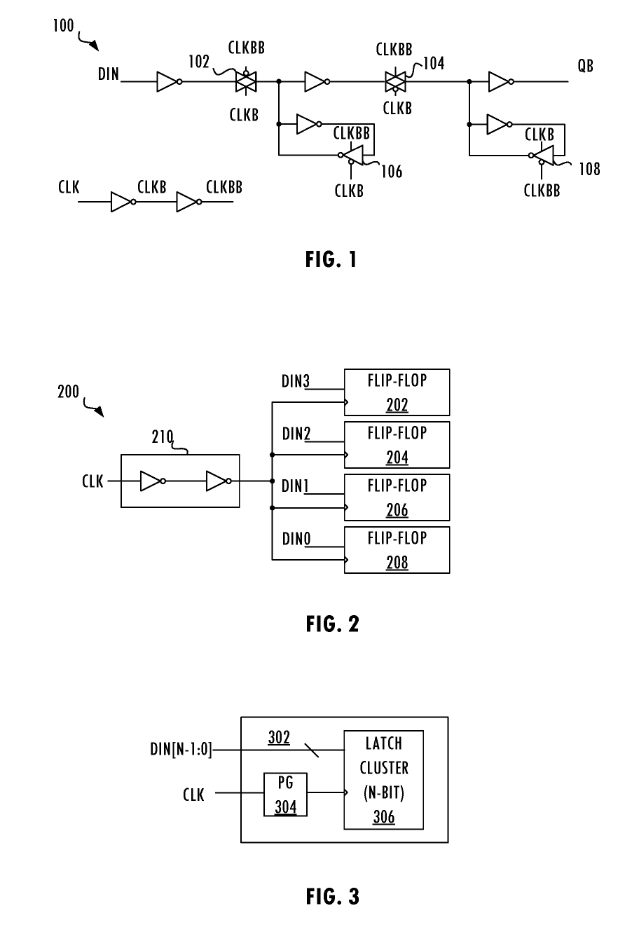

Referring to FIG. 1, a conventional low-power master-slave flip-flop includes pass-gate (i.e., transmission gate) 102 and pass-gate 104, which require two clock phases (i.e., a clock signal distributed on two separate transmission lines, e.g., CLKB and CLKBB). For low power designs, these conventional low-power master-slave flip-flops include devices sized to minimum allowable widths of the target semiconductor manufacturing technology. Pass-gates 102 and 104 and clocked devices 106 and 108 in keeper circuits of master and slave latches present a substantial load (e.g., gate load and wire load) on the clock net and the requirement of two clock phases. The conventional low-power master-slave flip-flop of FIG. 1 consumes substantial power, even when the conventional low-power master-slave flip-flop has a static state.

In emerging manufacturing technologies (e.g., FinFET manufacturing technology), wire contributions to the overall load have increased significantly, may dominate the gate loading, and may increase internal power consumption of the conventional edge-triggered master-slave flip-flop. For example, in a conventional integrated circuit using standard master-slave flip-flops, the internal dynamic power consumption may range from 50% to as high as 80% of the local dynamic power consumption. Techniques that may reduce the power consumption of a flip-flop include multi-bit master-slave flip-flops. Referring to FIG. 2, a multi-bit master-slave flip-flop shares the clock buffer 210 across multiple master-slave flip-flops. For example, multi-bit master-slave flip-flop 200 amortizes the cost of clock buffer 210 (e.g., two serially coupled inverters) over flip-flops 202, 204, 206 and 208, thereby reducing the gate load overhead on clock signal CLK. An N-bit master-slave flip-flop substantially reduces power consumption with respect to N individual master-slave flip-flops. However, further reductions to dynamic power consumption are desired, since the two-phase clocking requirement still consumes substantial amounts of power by switching large amounts of wire capacitance associated with distribution of the two clock phases.

Reduction of flip-flop power consumption may be achieved using a pulsed flip-flop technique. In a pulsed flip-flop, only a single latch (e.g., a single active high latch for rising edge operation and a single active low latch for falling-edge operation) is included in the flip-flop. However, to guarantee edge-triggered behavior with the latch, pulse-generator clock shaping circuitry is required. Referring to FIG. 3, as a result, a pulsed flip-flop requires a grouping of pulse generator 304 and a latch, as illustrated in FIG. 3. Pulsed flip-flop 302 is an exemplary N-bit flip-flop that includes latch cluster 306 with pulse generator 304. To reduce the overhead of the pulse-generator per bit, pulse generator 304 is shared across multiple latches, to create a structure similar to multi-bit master-slave flip-flop 200 of FIG. 2.

Pulsed flip-flops consume substantially less clock power than a standard master-slave flip-flop or even a multi-bit master-slave flip-flop described above. However, pulsed flip-flops require a pulsed clock signal that is generated by a pulse-generator. That pulsed clock signal has a duty cycle that is skewed with respect to clock signal CLK to ensure that the hold time of the pulsed flip-flop is sufficiently small. Yet, the pulsed clock still needs to be wide enough to ensure that the latch is writable. That is, the pulsed clock, which is generated from clock signal CLK and has an extra insertion delay, may have an active pulse width that is up to 5 or 6 gate delays, which accounts for process variations. As a result, the hold time requirement of the pulsed flip-flop can be significantly greater than the hold time of a standard master slave flip-flop or multi-bit flip-flop, which can heavily penalize an integrated circuit design for a target application. The pulsed flip-flop trades off reductions in dynamic power consumption with the cost of increased hold buffering.

A native edge-triggered master-slave flip-flop topology reduces power consumption without drawbacks of schemes described above. The native edge-triggered master-slave flip-flop topology provides clock power reduction comparable to that of the pulsed flip-flop for small bank sizes (i.e. smaller multi-bit clusters) but does not have the hold time or writability overhead since the topology maintains a master-slave configuration. The native edge-triggered master-slave flip-flop topology eliminates a multi-phase clock requirement. The single-phase clocking reduces the wire loading on the clock net. In addition, the low-power master-slave flip-flop topology reduces the number of clocked transistors driven by the clock net in each instantiation of a flip-flop, thereby reducing the required integrated circuit area.

As referred to herein, a native circuit (i.e., a native latch or native edge-triggered master-slave flip-flop) is a circuit that can be driven directly by the clock net (i.e., clock terminal) of the latch, and the circuit topology guarantees appropriate behavior. The native edge-triggered master-slave flip-flop topology includes two native latches: one native latch operates as an active low latch with respect to a signal on the clock net (i.e., a native B-latch) and another that operates as an active high latch with respect to a signal on the clock net (i.e., a native A-latch).

An exemplary native rising-edge-triggered master-slave flip-flop is formed by coupling a native B-latch to receive input data. That native B-latch is configured to provide an intermediate signal to a native A-latch. Similarly, a native falling-edge-triggered master-slave flip-flop is formed by coupling a native A-latch to receive input data. That native A-latch is configured to provide an intermediate signal to a native B-latch. The native edge-triggered master-slave flip-flops each have relatively low clock net loading. Each of the latches in a native edge-triggered master-slave flip-flop includes no more than three clocked transistors (e.g., two n-type transistors and one p-type transistor in a native B-latch or one n-type transistor and two p-type transistors in a native A-latch), for a total of, at most, six clocked transistors. Each of the clocked transistors is driven directly from the clock net, which is affected by reduced wire loading and gate capacitance loading.

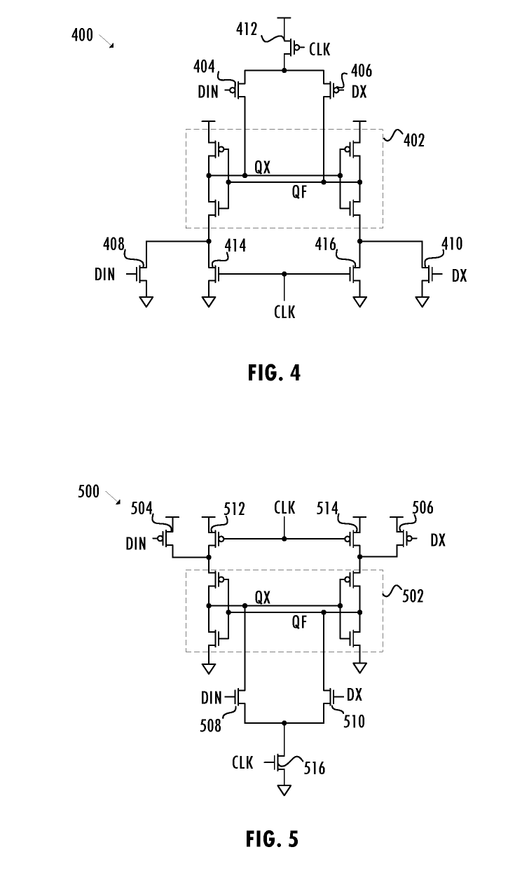

Referring to FIGS. 4 and 5, native B-latch 400 and native A-latch 500 each have a differential circuit topology that receives input signal DIN and its complement, complementary input signal DX, on p-type input devices. Each of the native latches also receives input signal DIN and complementary input signal DX on n-type input devices. Native B-latch 400 receives input signal DIN and complementary input signal DX on p-type input device 404 and p-type input device 406, respectively. A low state of clock signal CLK received by clocked device 412 causes one of p-type input devices 404 and 406 to write logic one onto a corresponding node of intermediate node QF and complementary intermediate node QX of storage element 402, which includes two cross-coupled pairs of complementary devices. Input signal DIN and complementary input signal DX, which are mutually exclusive signals, cause one of n-type input device 408 and n-type input device 410 to provide a ground reference to storage element 402 to guarantee no write contention during the low state of clock signal CLK. Clocked devices 414 and 416 provide a stable ground reference during a high state of clock signal CLK. During the high state of clock signal CLK, input signal DIN and complementary input signal DX can change rapidly. The stable ground reference provided by clocked devices 414 and 416 ensures that stored data is stable, i.e., does not change during the high state of clock signal CLK. Positive feedback causes p-type devices of storage element 402 to switch the state of the latch.

Native A-latch 500 has a circuit topology that is complementary to the circuit topology of native B-latch 400. N-type input devices 508 and 510 receive complementary versions of the input signal, input signal DIN and complementary input signal DX, respectively. A high state of clock signal CLK received by clocked device 516 causes one of n-type input devices 508 and 510 to write logic zero onto a corresponding node of intermediate node QF and complementary intermediate node QX of storage element 502, which includes two cross-coupled pairs of complementary devices. Input signal DIN and complementary input signal DX, which are mutually exclusive signals, cause one of p-type input devices 504 and 506 to provide a high voltage reference to storage element 502 to guarantee no write contention during the high state of clock signal CLK. Clocked devices 512 and 514 provide a high voltage reference during a low state of clock signal CLK. During the low state of clock signal CLK, input signal DIN and complementary input signal DX can change rapidly. Clock devices 512 and 514 ensure a stable high voltage reference that prevents data stored in the latch from being altered during the low state of clock signal CLK. Positive feedback causes n-type devices of storage element 502 to switch the state of native A-latch 500.

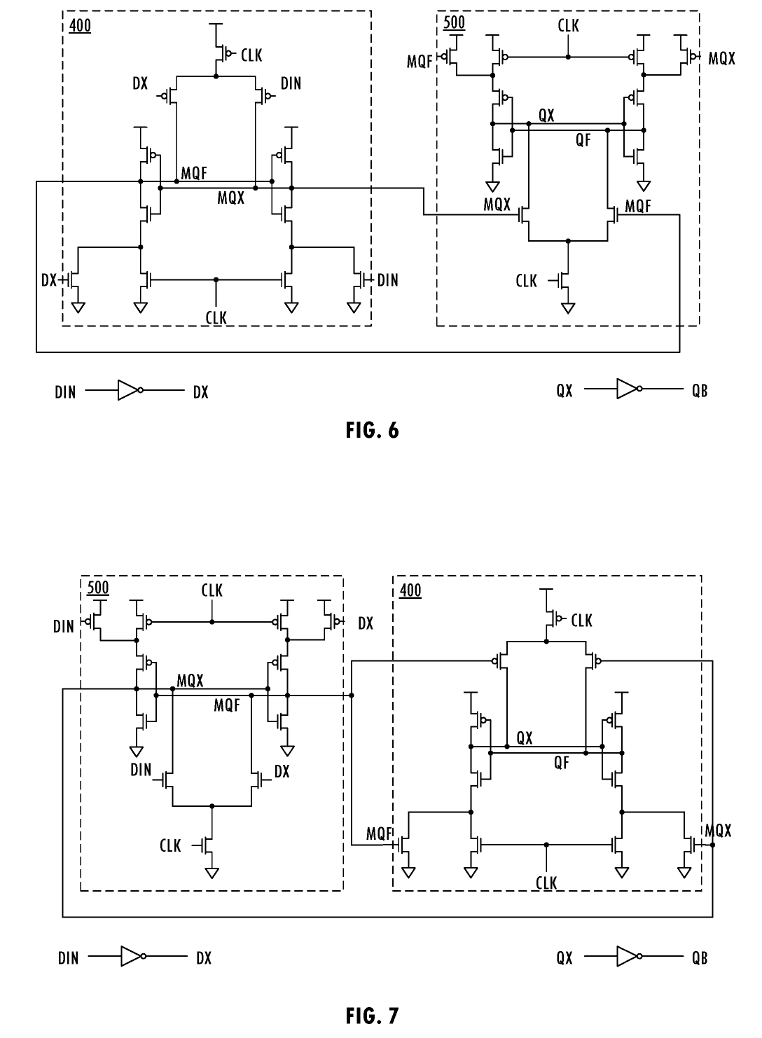

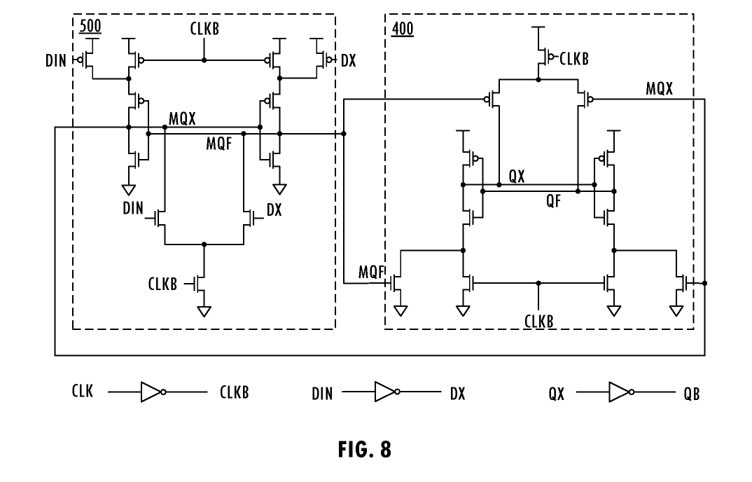

Referring to FIG. 6, in at least one embodiment of a native edge-triggered master-slave flip flop, a rising-edge triggered master slave flip-flop is formed by coupling native B-latch 400 to receive input signal DIN and complementary input signal DX. Native B-latch 400 is configured to provide intermediate signal MQF and complementary intermediate signal MQX from native B-latch 400 to the input devices of native A-latch 500, which generates output signal QF and complementary output signal QX. Referring to FIG. 7, in at least one embodiment of a native edge-triggered master-slave flip flop, a falling-edge triggered flip-flop is formed by coupling native A-latch 500 to input signal DIN and complementary input signal DX. Native A-latch 500 provides intermediate signal MQF and complementary intermediate signal MQX to the input devices of native B-latch 400, which generates output signal QF and complementary output signal QX. FIG. 8 illustrates another embodiment of a native falling-edge-triggered master-slave flip-flop with further reduced loading of the clock net. This circuit uses the native falling-edge-triggered master-slave flip-flop of FIG. 7, but includes an additional inverter coupled to the clock terminal of the flip-flop to generate inverted clock signal CLKB. The embodiment of FIG. 8 still uses a single-phase clock, since inverted clock signal CLKB is directly coupled to native A-latch 500 and native B-latch 400 without requiring an additional phase. Use of the inverted clock signal CLB makes the native falling-edge-triggered master-slave flip-flop behave as a rising-edge-triggered master-slave flip-flop. The additional inverter reduces the loading of the flip-flop on the local clock distribution (e.g., CTS), but causes the native falling-edge-triggered master-slave flip-flop to be slightly less power efficient and have slightly larger area than the native falling-edge-triggered master-slave flip-flop of FIG. 7. An exemplary integrated circuit design uses both variants of native falling-edge-triggered master-slave flip-flops according to the particular circuit needs.

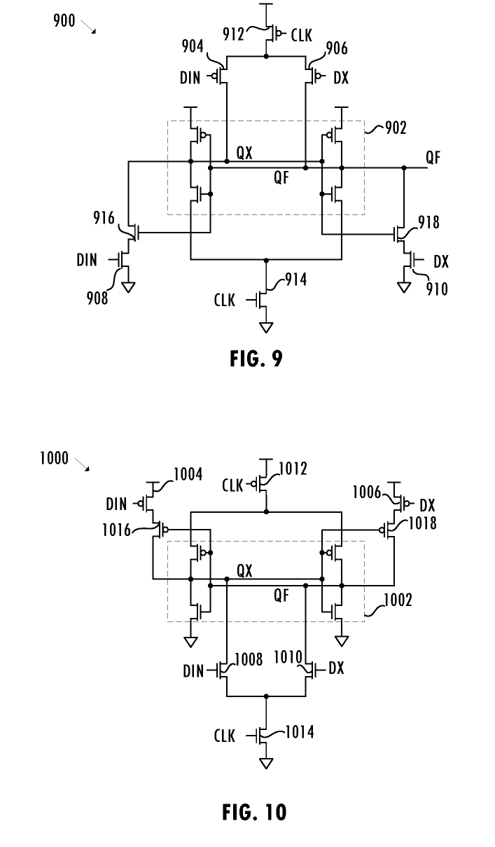

Referring to FIGS. 9 and 10, other embodiments of native A-latches and native B-latches can achieve clock power savings that when configured as native edge-triggered master-slave flip-flops, may match or exceed the power consumption savings of pulsed flip-flops for small multi-bit clusters but will not have the hold time or writability overhead associated with pulsed flip-flops. Native B-latch 900 and native A-latch 1000 have reduced clock loading as compared to native B-latch 400 and native A-latch 500. Native B-latch 900 and native A-latch 1000 each include only two transistors each driven by the clock net (e.g., clocked device 914 and clocked device 912 of native B-latch 900 and clocked device 1014 and clocked device 1012 of native A-latch 1000), as compared to the three transistors driven by the clock net in each of native B-latch 400 and native A-latch 500. In addition, native B-latch 900 and native A-latch 1000 include storage elements 902 and 1002, respectively, and input devices 904, 906, 908, and 910 and input devices 1004, 1006, 1008, and 1010, respectively. State nodes of native B-latch 900 control devices 916 and 918 to provide a stable ground reference to storage element 902 through devices 908 and 910, respectively, during the low state of clock signal CLK. The state nodes of native A-latch 1000 control devices 1016 and 1018 to provide a stable high voltage reference to storage element 1002 through devices 1004 and 1006, respectively, during the high state of clock signal CLK. Native B-latch 900 and native A-latch 1000 may be configured as a native edge-triggered master-slave flip-flop having a total of four clocked transistors as compared to the six clocked transistors of native edge-triggered master-slave flip-flops formed using B-latch 400 and A-latch 500.

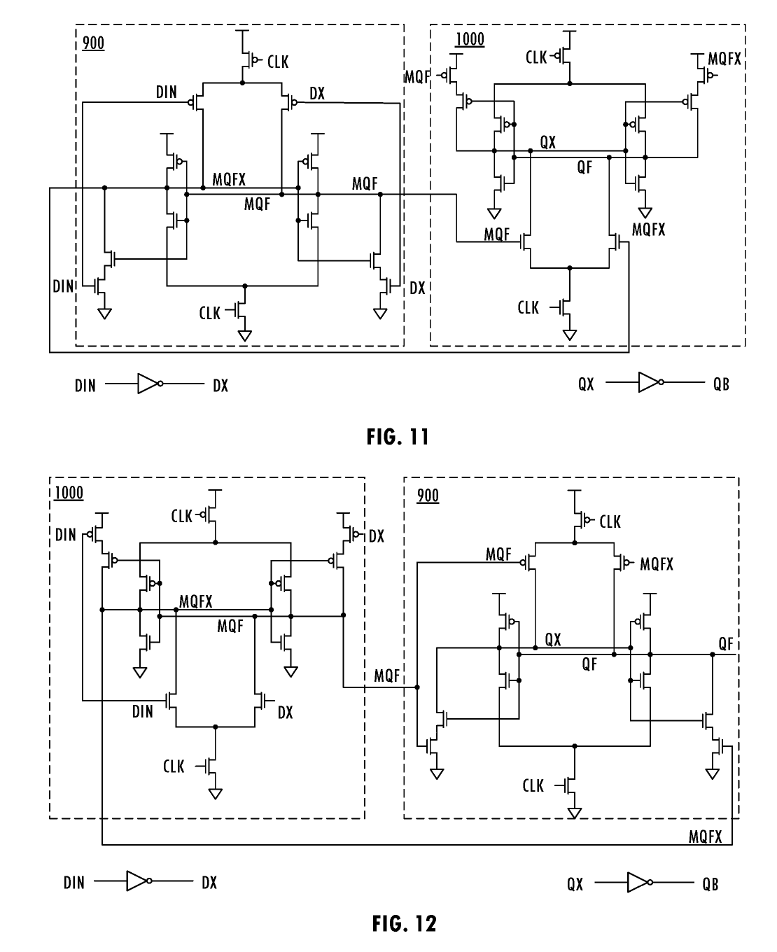

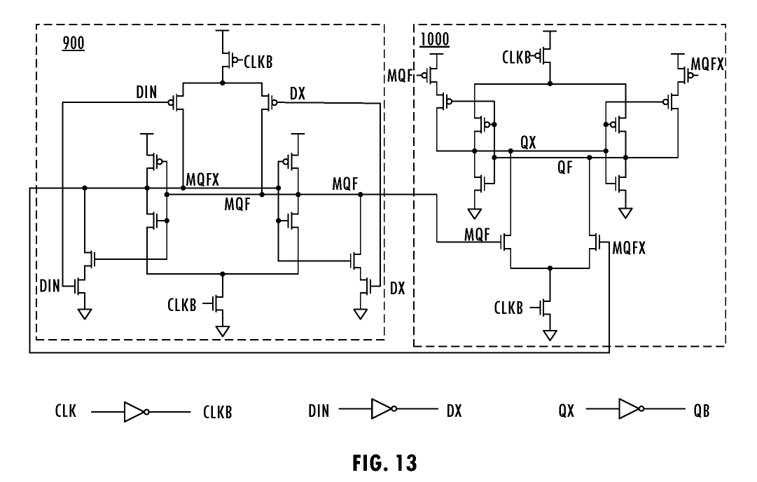

Referring to FIG. 11, in at least one embodiment of a native edge-triggered master-slave flip flop, a rising-edge triggered master slave flip-flop is formed by coupling native B-latch 900 to receive input signal DIN and complementary input signal DX. Native B-latch 900 is configured to provide intermediate signal MQF and complementary intermediate signal MQX to the input devices of native A-latch 1000, which generates output signal QF and complementary output signal QX. Referring to FIG. 12, in at least one embodiment of a native edge-triggered master-slave flip flop, a falling-edge triggered flip-flop is formed by coupling native A-latch 1000 to input signal DIN and complementary input signal DX. Native A-latch 1000 provides intermediate signal MQF and complementary intermediate signal MQX to the input devices of native B-latch 900, which generates output signal QF and complementary output signal QX. FIG. 13 illustrates another embodiment of a falling-edge-triggered master-slave flip-flop with further reduced loading of the clock net. This circuit uses the native rising-edge-triggered master-slave flip-flop of FIG. 11, but includes an additional inverter coupled to the clock terminal of the flip-flop to generate inverted clock signal CLKB. Inverted clock signal CLKB makes the flip-flop behave like a falling-edge-triggered master-slave flip-flop. The embodiment of FIG. 13 still uses a single-phase clock, since inverted clock signal CLKB is directly coupled to native A-latch 1000 and native B-latch 900 without requiring an additional phase. The additional inverter reduces the loading on the local clock distribution (e.g., CTS), but causes the falling-edge-triggered master-slave flip-flop to be slightly less power efficient and to have slightly larger area than the native rising-edge-triggered master-slave flip-flop of FIG. 11. An exemplary integrated circuit design uses both variants of native falling-edge-triggered master-slave flip-flops according to the particular circuit needs.

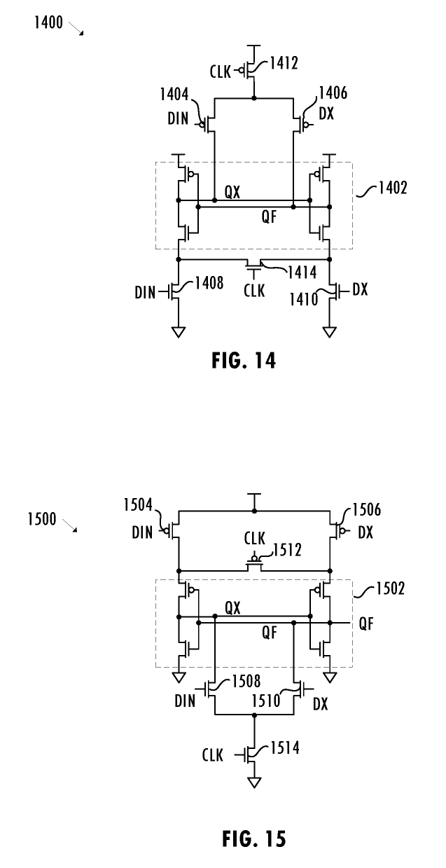

Other embodiments of native latches can achieve dynamic power savings that when configured in native edge-triggered master-slave flip-flops, may match or exceed the dynamic power savings of pulsed flip-flop power savings for small multi-bit clusters, without the associated hold time or writability overhead, and have a reduced transistor count as compared to B-latch 400, A-latch 500, B-latch 900, and A-latch 1000. Referring to FIGS. 14 and 15, native B-latch 1400 and native A-latch 1500 each include only two transistors each driven by the clock net (e.g., clocked device 1412 and clocked device 1414 of native B-latch 1400 and clocked device 1512 and clocked device 1514 of native A-latch 1500). In addition, native B-latch 1400 and native A-latch 1500 include storage elements 1402 and 1502, respectively, and input devices 1404, 1406, 1408, and 1410 and input devices 1504, 1506, 1508, and 1510, respectively. Native B-latch 1400 and A-latch 1500 include a total of ten transistors each and achieve similar power and performance results as B-latch 400, A-latch 500, B-latch 900, and A-latch 1000, but require less area.

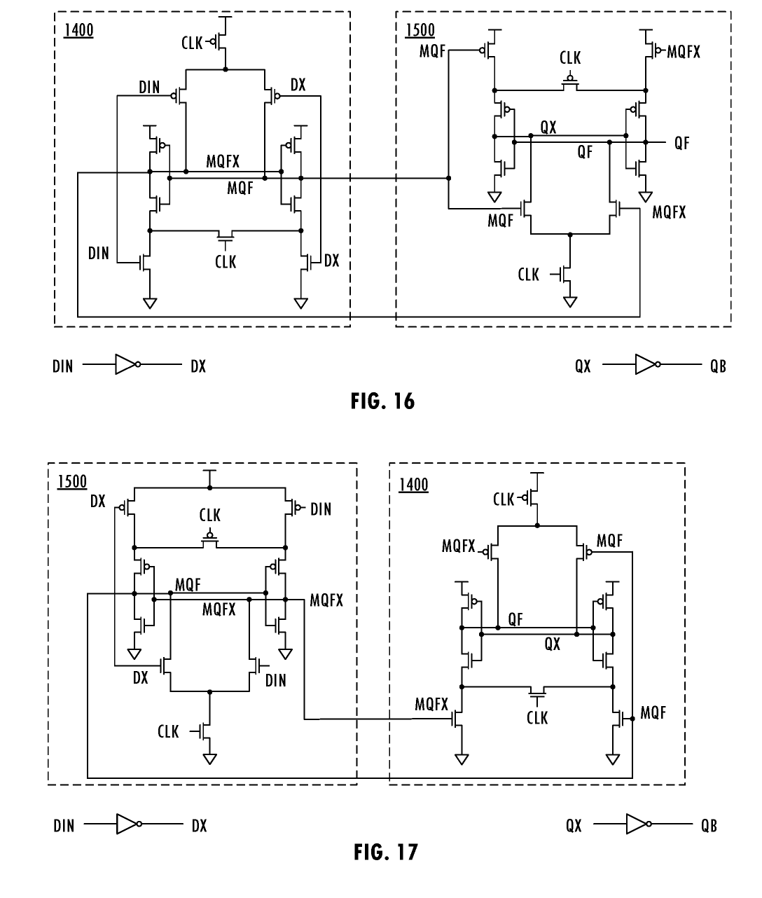

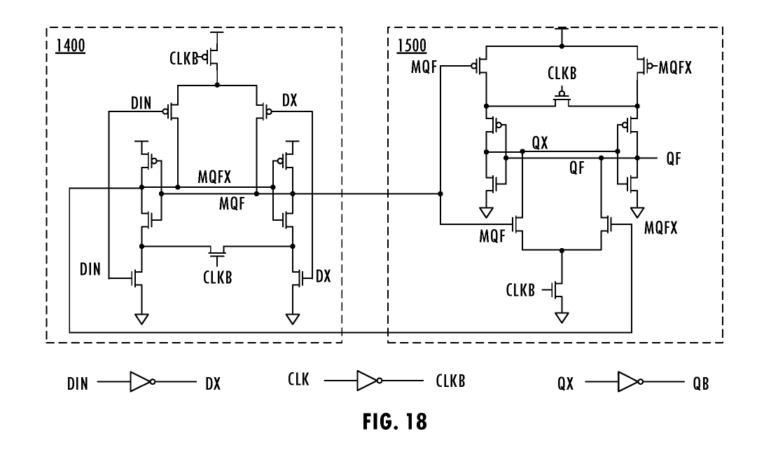

Referring to FIG. 16, in at least one embodiment of a native edge-triggered master-slave flip flop, a rising-edge triggered master slave flip-flop is formed by coupling native B-latch 1400 to receive input signal DIN and complementary input signal DX. Native B-latch. Native B-latch 1400 is configured to provide intermediate signal MQF and complementary intermediate signal MQX to the input devices of native A-latch 1500, which generates output signal QF and complementary output signal QX. Referring to FIG. 17, in at least one embodiment of a native edge-triggered master-slave flip flop, a falling-edge triggered flip-flop is formed by coupling native A-latch 1500 to input signal DIN and complementary input signal DX and providing intermediate signal MQF and complementary intermediate signal MQX from native A-latch 1500 to the input devices of native B-latch 1400, which generates output signal QF and complementary output signal QX. FIG. 18 illustrates another embodiment of a falling-edge-triggered master-slave flip-flop with further reduced loading of the clock net. This circuit uses the native rising-edge-triggered master-slave flip-flop of FIG. 16, but includes an additional inverter coupled to the clock terminal of the flip-flop to generate inverted clock signal CLKB. The inverted clock signal CLKB makes it behave like a falling-edge-triggered flip-flop. The embodiment of FIG. 18 still uses a single-phase clock, since inverted clock signal CLKB is directly coupled to native A-latch 1500 and native B-latch 1400 without requiring an additional phase. The additional inverter reduces the loading on the local clock distribution (e.g., CTS), causes the native rising-edge-triggered master-slave flip-flop to be slightly less power efficient and to have slightly larger area that the native rising-edge-triggered master-slave flip-flop of FIG. 16. An exemplary integrated circuit design uses both variants of native falling-edge-triggered master-slave flip-flops according to the particular circuit needs.

The native edge-triggered master-slave flip-flops described herein may substantially reduce local dynamic power consumption as compared to conventional master-slave flip-flops, but also have reduced hold times and reduced area as compared to other reduced power consumption solutions (e.g., pulsed flip-flops). While circuits and physical structures have been generally presumed in describing embodiments of the invention, it is well recognized that in modern semiconductor design and fabrication, physical structures and circuits may be embodied in computer-readable descriptive form suitable for use in subsequent design, simulation, test or fabrication stages. Structures and functionality presented as discrete components in the exemplary configurations may be implemented as a combined structure or component. Various embodiments of the invention are contemplated to include circuits, systems of circuits, related methods, and tangible computer-readable medium having encodings thereon (e.g., VHSIC Hardware Description Language (VHDL), Verilog, GDSII data, Electronic Design Interchange Format (EDIF), and/or Gerber file) of such circuits, systems, and methods, all as described herein. In addition, the computer-readable media may store instructions as well as data that can be used to implement the invention. The instructions/data may be related to hardware, software, firmware or combinations thereof.

The description of the invention set forth herein is illustrative, and is not intended to limit the scope of the invention as set forth in the following claims. For example, while the invention has been described in an embodiment functioning as a master-slave flip-flop, one of skill in the art will appreciate that the teachings herein can be utilized with other native A-latch or native B-latch configurations. Variations and modifications of the embodiments disclosed herein, may be made based on the description set forth herein, without departing from the scope of the invention as set forth in the following claims.

1. An apparatus comprising:
a clock node configured to receive a single-phase clock signal;
an input node configured to receive an input signal;
a complementary input node configured to receive a complementary input signal that is complementary to the input signal;
a first differential latch comprising:
a first pair of complementary devices including a first device of a first type and a second device of a second type;
a second pair of complementary devices cross-coupled to the first pair of complementary devices, the second pair of complementary devices including a third device of the first type and a fourth device of the second type;
a first pair of input devices including a fifth device of the first type and a sixth device of the first type; and
a second pair of input devices including a seventh device of the second type and an eighth device of the second type,
wherein the first pair of input devices and the second pair of input devices are configured to write an intermediate node with the complementary input signal and to write a complementary intermediate node with the input signal in response to a first state of the single-phase clock signal.

2. The apparatus, as recited in claim 1,
wherein each of the first pair of input devices has a source terminal connected to a drain terminal of a device having a gate terminal connected to the clock node, and
wherein each of the second pair of input devices has a source terminal connected to a power supply node, and
wherein a drain terminal of the seventh device is connected to a source terminal of the second device and a drain terminal of the eighth device is connected to a source terminal of the fourth device.

3. The apparatus, as recited in claim 1, further comprising:
a ninth device of the first type and having a gate terminal connected to the clock node, a source terminal connected to a first power supply node, and a drain terminal connected to a source terminal of the fifth device and a source terminal of the sixth device;
a tenth device of the second type and having a gate terminal connected to the clock node, a source terminal connected to a second power supply node, and a drain terminal connected to a drain terminal of the seventh device and a source terminal of the second device; and
an eleventh device of the second type and having a gate terminal connected to the clock node, a source terminal connected to the second power supply node, and a drain terminal connected to a drain terminal of the eighth device and a source terminal of the fourth device.

4. The apparatus, as recited in claim 1, further comprising:
a ninth device of the first type and having a gate terminal connected to the clock node, a source terminal connected to a first power supply node, and a drain terminal connected to a source terminal of the fifth device and a source terminal of the sixth device;
a tenth device of the second type and having a gate terminal connected to the clock node, a source terminal connected to a second power supply node, and a drain terminal connected to a source terminal of the second device and a source terminal of the fourth device;
an eleventh device of the second type having a gate terminal connected to the intermediate node, a source terminal connected to a drain terminal of the seventh device, and a drain terminal connected to the complementary intermediate node; and
a twelfth device of the second type having a gate terminal coupled to the complementary intermediate node, a source terminal connected to a drain terminal of the eighth device, and a drain terminal connected to the intermediate node.

5. The apparatus, as recited in claim 1,
a ninth device of the first type and having a gate terminal connected to the clock node, a source terminal connected to a first power supply node, and a drain terminal connected to a source terminal of the fifth device and a source terminal of the sixth device; and
a tenth device of the second type and having a gate terminal connected to the clock node, a first terminal connected to a drain terminal of the seventh device, and a second terminal connected to a drain terminal of the eighth device.

6. The apparatus, as recited in claim 1, further comprising:
a second differential latch connected to the clock node, the second differential latch being complementary to the first differential latch and configured to update an output node and a complementary output node based on the intermediate node and the complementary intermediate node and in response to a second state of the single-phase clock signal.

7. The apparatus, as recited in claim 6, wherein the first and second differential latches are configured as an edge-triggered master-slave flip-flop.

8. The apparatus, as recited in claim 7, wherein the edge-triggered master-slave flip-flop does not include a transmission gate.

9. The apparatus, as recited in claim 7, wherein the edge-triggered master-slave flip-flop operates using the single-phase clock signal and no additional clock signal phases.

10. The apparatus, as recited in claim 7, wherein the edge-triggered master-slave flip-flop includes at most six transistors driven by the single-phase clock signal.

11. The apparatus, as recited in claim 7, wherein the edge-triggered master-slave flip-flop includes only four transistors connected to the clock node.

12. The apparatus, as recited in claim 6, wherein the second differential latch comprises:
a third pair of complementary devices including a ninth device of the first type and a tenth device of the second type;
a fourth pair of complementary devices cross-coupled to the third pair of complementary devices, the fourth pair of complementary devices including an eleventh device of the first type and a twelfth device of the second type;
a third pair of input devices including a thirteenth device of the first type and a fourteenth device of the first type; and
a fourth pair of input devices including a fifteenth device of the second type and a sixteenth device of the second type,
wherein the third pair of input devices and the fourth pair of input devices are configured to write an output node with a complementary intermediate signal on the intermediate node and to write a complementary output node with an intermediate signal on the complementary intermediate node in response to a second state of the single-phase clock signal.

13. A method comprising:
providing a first reference voltage to a first storage element;
providing a second reference voltage to one of a first node of the first storage element and a complementary first node of the first storage element according to an input signal and a complementary input signal during a first state of a clock signal; and
writing the first node with the complementary input signal and writing the complementary first node with the input signal using the first reference voltage and the second reference voltage during the first state of the clock signal.

14. The method, as recited in claim 13, further comprising:
providing the second reference voltage to a second storage element;
providing the first reference voltage to one of a second node of the second storage element and a complementary second node of the second storage element according to an intermediate signal on the complementary first node and a complementary intermediate signal on the first node during a second state of the clock signal;
writing the second node with the intermediate signal and writing the complementary second node with the complementary intermediate signal using the first reference voltage and the second reference voltage during the second state of the clock signal.

15. The method, as recited in claim 14, further comprising:
providing the second reference voltage to the first storage element during the second state of the clock signal; and
providing the first reference voltage to the second storage element during the first state of the clock signal.

16. The method, as recited in claim 14, wherein the first storage element and the second storage element are included in an edge-triggered master-slave flip-flop using the clock signal and no additional phases of the clock signal.

17. The method, as recited in claim 16, wherein the edge-triggered master-slave flip-flop includes at most six transistors driven by the clock signal.

18. The method, as recited in claim 16, wherein the edge-triggered master-slave flip-flop includes only four transistors connected to the clock signal.

19. An apparatus comprising:
means for providing a first reference voltage to one of a first node of a first storage element and a complementary first node of the first storage element according to an input signal and a complementary input signal during a first state of a clock signal; and
means for writing the first node with the complementary input signal and writing the complementary first node with the input signal using the first reference voltage and a second reference voltage during the first state of the clock signal.

20. The apparatus, as recited in claim 19,
means for providing the second reference voltage to one of a second node of a second storage element and a complementary second node of the second storage element according to an intermediate signal on the complementary first node and a complementary intermediate signal on the first node during a second state of the clock signal; and
means for writing the second node with the intermediate signal and writing the complementary second node with the complementary intermediate signal using the first reference voltage and the second reference voltage during the second state of the clock signal.
